(19) United States
(12) Patent Application Publication
(10) Pub. No.: US 2026/0250842 A1
(43) Pub. Date: Aug. 27, 2026

(54) SUBSTRATE PROCESSING METHOD AND SUBSTRATE PROCESSING SYSTEM

(71) Applicant: Tokyo Electron Limited, Tokyo (JP)

(72) Inventors: Mayu KANEKO, Yamanashi (JP); Makoto WADA, Yamanashi (JP); Yuto NAKAZAWA, Yamanashi (JP); Yoshinori MORISADA, Yamanashi (JP); Nobuo MATSUKI, Yamanashi (JP)

(21) Appl. No.: 19/465,174

(22) Filed: Jan. 30, 2026

(30) Foreign Application Priority Data
Feb. 4, 2025 (JP) 2025-017153

(51) Int. Cl. C23C 16/455; C23C 16/30; C23C 16/36; C23C 16/40; C23C 16/56; H01J 37/32

(52) U.S. Cl. CPC C23C 16/45536; C23C 16/56; H01J 37/3244; C23C 16/308; C23C 16/36; C23C 16/401; H01J 2237/3321

(57) ABSTRACT

Substrate processing method and system for embedding silicon-containing film in recess in substrate are provided. Substrate processing method for embedding silicon-containing film in recess includes (a) forming first fluidic film having first viscosity in recess by exposing substrate to plasma of first processing gas containing first silicon-containing gas and second silicon-containing gas different from first silicon-containing gas; (b) forming first silicon-containing film having voids by modifying first fluidic film by exposing substrate to plasma of first modifying gas; (c) forming second fluidic film having second viscosity lower than first viscosity in recess and voids in first silicon-containing film by exposing substrate to plasma of second processing gas containing first and second silicon-containing gases; and (d) forming second silicon-containing film by modifying second fluidic film by exposing substrate to plasma of second modifying gas.

### CROSS-REFERENCE TO RELATED APPLICATION

The present application claims priority under 35 U.S.C. § 119 to Japanese Patent Application No. 2025-017153, filed Feb. 4, 2025, the contents of which are incorporated herein by reference in their entireties.

### BACKGROUND OF THE INVENTION

### Field of the Invention

The present disclosure relates to a substrate processing method and a substrate processing system.

### Description of the Related Art

Japanese Patent Application Laid-Open Publication No. 2022-111764 discloses a method for forming a silicon-containing film in a recess formed in the surface of a substrate, which includes (a) forming a fluidic film in the recess by exposing the substrate, which is regulated to a first temperature, to a plasma formed from a processing gas containing halogen-containing silane, and (b) hardening the fluidic film by thermally treating the substrate at a second temperature higher than the first temperature.

### SUMMARY OF THE INVENTION

To achieve the object described above, according to one aspect, a substrate processing method for embedding a silicon-containing film in a recess is provided, including: (a) forming a first fluidic film having a first viscosity in the recess by exposing a substrate to a plasma formed from a first processing gas containing a first silicon-containing gas and a second silicon-containing gas different from the first silicon-containing gas; (b) forming a first silicon-containing film having voids by modifying the first fluidic film by exposing the substrate to a plasma formed from a first modifying gas; (c) forming a second fluidic film having a second viscosity lower than the first viscosity in the recess and in the voids in the first silicon-containing film by exposing the substrate to a plasma formed from a second processing gas containing the first silicon-containing gas and the second silicon-containing gas; and (d) forming a second silicon-containing film by modifying the second fluidic film by exposing the substrate to a plasma formed from a second modifying gas.

### BRIEF DESCRIPTION OF THE DRAWINGS

FIG. 1 illustrates an example of a substrate processing system according to an embodiment;

FIG. 2 is a flowchart illustrating an example of a substrate processing method according to an embodiment;

FIG. 3 is an example of a schematic cross-sectional view of a substrate;

FIG. 4 is an example of a schematic cross-sectional view of a substrate;

FIG. 5 is an example of a schematic cross-sectional view of a substrate;

FIG. 6 is an example of a schematic cross-sectional view of a substrate;

FIG. 7 is an example of a schematic cross-sectional view of a substrate;

FIG. 8 is an example of a chemical reaction formula;

FIG. 9 is an example of a chemical reaction formula;

FIG. 10 is an example of a chemical reaction formula;

FIG. 11 is an example of a chemical reaction formula;

FIG. 12A is an example of a view showing the relationship between the ratio of a crosslinking gas and the viscosity of a fluidic film;

FIG. 12B is an example of a diagram showing the relationship between the ratio of a crosslinking gas and the viscosity of a fluidic film;

FIG. 13 is an example of a schematic cross-sectional view showing the state of a substrate during CMP treatment;

FIG. 14A is an example of a schematic cross-sectional view showing a state of a substrate; and

FIG. 14B is an example of a schematic cross-sectional view showing a state of a substrate.

### DETAILED DESCRIPTION OF THE DISCLOSURE

Hereinafter, embodiments for implementing the present disclosure will be described with reference to the drawings. In the drawings, the same components are denoted by the same reference numerals and redundant descriptions may be omitted.

### [Substrate Processing System]

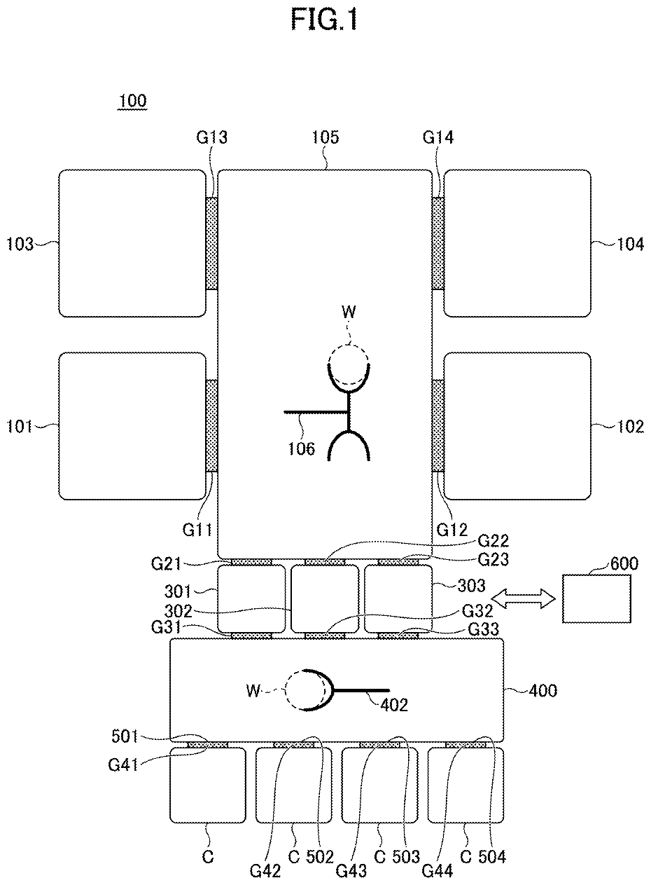

A substrate processing system 100 used in a substrate processing method according to an embodiment will be described with reference to FIG. 1. FIG. 1 is a diagram showing an example of a substrate processing system 100 according to an embodiment.

The substrate processing system 100 includes processing apparatuses 101 to 104, a vacuum conveying chamber 105, load lock chambers 301 to 303, an open-air conveying chamber 400, load ports 501 to 504, and a controller 600.

The processing apparatuses 101 to 104 are connected to the vacuum conveying chamber 105 via gate valves G11 to G14, respectively. The interiors of the processing apparatuses 101 to 104 are depressurized to a predetermined vacuum atmosphere, and desired processes are performed on the substrate W in the interiors.

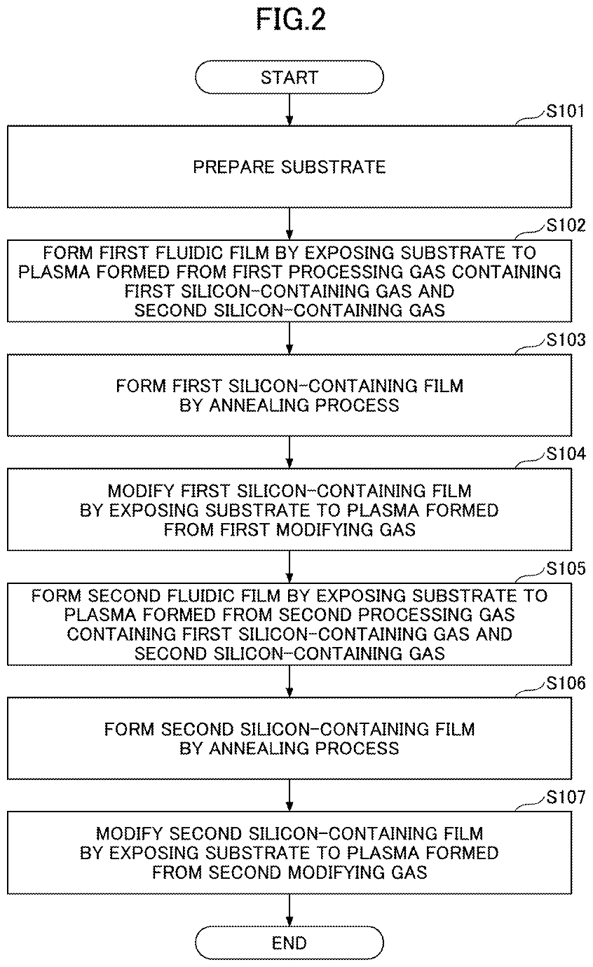

The processing apparatus 101 is a processing apparatus (a film-forming apparatus) for performing the process of step S102 in FIG. 2 described later (a process for forming a first fluidic film 20), to form a fluidic film in a recess 11 of the substrate W.

The processing apparatus 101 is, for example, a plasma CVD (plasma-enhanced chemical vapor deposition) apparatus. The processing apparatus 101 includes, for example, a processing vessel, a substrate support provided in the processing vessel, a gas supply for supplying a first processing gas into the processing vessel, and a plasma former for forming a plasma of the first processing gas. The controller 600 controls the processing apparatus 101 to form a plasma of the first processing gas and form the first fluidic film 20 on the substrate W.

The processing apparatus 102 is a processing apparatus (a heating apparatus) for performing the process of step S103 in FIG. 2 described later (a first annealing process), to anneal the substrate W. The processing apparatus 102 is also a processing apparatus (a modifying apparatus) for performing the process of step S104 in FIG. 2 described later (a first modifying process), to modify the substrate W.

The processing apparatus 102 includes, for example, a processing vessel, a substrate support provided in the processing vessel, a gas supply for supplying an inert gas (Ar gas) into the processing vessel, and a heater for heating the substrate W. The controller 600 controls the processing apparatus 102 to heat the substrate W in an inert gas (Ar gas) atmosphere, to perform an annealing process on the substrate W. The processing apparatus 102 includes, for example, a processing vessel, a substrate support provided in the processing vessel, a gas supply for supplying a first modifying gas into the processing vessel, and a plasma former for forming a plasma of the first modifying gas. The controller 600 controls the processing apparatus 102 to form a plasma of the first modifying gas, to perform a modifying process on the substrate W. The processing apparatus 103 is a processing apparatus (a film-forming apparatus) for performing the process of step S105 in FIG. 2 described later (a process for forming a second fluidic film 30), to form a fluidic film in voids 27 in the substrate W.

The processing apparatus 103 is, for example, a plasma CVD (plasma-enhanced chemical vapor deposition) apparatus. The processing apparatus 103 includes, for example, a processing vessel, a substrate support provided in the processing vessel, a gas supply for supplying the second processing gas into the processing vessel, and a plasma former for forming a plasma of the second processing gas. The controller 600 controls the processing apparatus 103 to form a plasma of a second processing gas to form a second fluidic film 30 on the substrate W.

The processing apparatus 104 is a processing apparatus (heating apparatus) for performing the process of step S106 in FIG. 2 described later (a second annealing process), to anneal the substrate W. The processing apparatus 104 is a processing apparatus (a modifying apparatus) for performing the process of step S107 in FIG. 2 described later (a second modifying process), to modify the substrate W. The processing apparatus 104 includes, for example, a VHF plasma source.

The processing apparatus 104 includes, for example, a processing vessel, a substrate support provided in the processing vessel, a gas supply for supplying an inert gas (Ar gas) into the processing vessel, and a heater for heating the substrate W. The controller 600 controls the processing apparatus 104 to heat the substrate W in an inert gas (Ar gas) atmosphere to anneal the substrate W. The processing apparatus 104 also includes, for example, a processing vessel, a substrate support provided in the processing vessel, a gas supply for supplying a second modifying gas into the processing vessel, and a plasma former for forming a plasma of the second modifying gas. The controller 600 controls the processing apparatus 104 to form a plasma of the second modifying gas to modify the substrate W.

The configuration of the processing apparatuses 101 to 104 shown in FIG. 1 is an example, and is non-limiting. For example, the ratio of the number of the processing apparatuses 101 to 104 may be appropriately selected. Further, the process of step S102 and the process of step S105 may be performed by the same processing apparatus. Further, the processes of steps S102 and S104 and the processes of steps S105 and S107 may be performed by the same processing apparatus. Further, regarding the processing apparatuses 102 and 104, it has been described that the annealing process and the modifying process are performed by the same processing apparatus. However, this is non-limiting, and the processing apparatus for performing the annealing process and the processing apparatus for performing the modifying process may be provided as separate processing apparatuses.

The interior of the vacuum conveying chamber 105 is depressurized to a predetermined vacuum atmosphere. The vacuum conveying chamber 105 is an example of a conveying apparatus for conveying the substrate W. The vacuum conveying chamber 105 is provided with a conveying mechanism 106 capable of conveying the substrate W in a depressurized state. The conveying mechanism 106 conveys the substrate W to the processing apparatuses 101 to 104 and to the load lock chambers 301 to 303.

The load lock chambers 301 to 303 are connected to the vacuum conveying chamber 105 via gate valves G21 to G23, and are connected to the open-air conveying chamber 400 via gate valves G31 to G33. The interiors of the load lock chambers 301 to 303 can be switched between an open-air atmosphere and a vacuum atmosphere.

The interior of the open-air conveying chamber 400 is in an open-air atmosphere, and, for example, a downflow of clean air is formed in the open-air conveying chamber 400. An aligner (not shown) for aligning the substrate W is provided in the open-air conveying chamber 400. The open-air conveying chamber 400 includes a conveying mechanism 402. The conveying mechanism 402 conveys the substrate W to the load lock chambers 301 to 303, to carriers C at the load ports 501 to 504 described later, and to the aligner.

The load ports 501 to 504 are provided in the wall surface of the open-air conveying chamber 400. A carrier C containing the substrate W or an empty carrier C is attached to the load ports 501 to 504 via the gate valves G41 to G44. For example, a Front Opening Unified Pod (FOUP) can be used as a carrier C.

The controller 600 controls each part of the substrate processing system 100. For example, the controller 600 controls the operations of the processing apparatuses 101 to 104, the operation of the conveying mechanisms 106 and 402, opening and closing of the gate valves G11 to G14, G21 to G23, G31 to G33, and G41 to G44, switching of the atmosphere in the load lock chambers 301 to 303, and the like.

### [Substrate Processing Method]

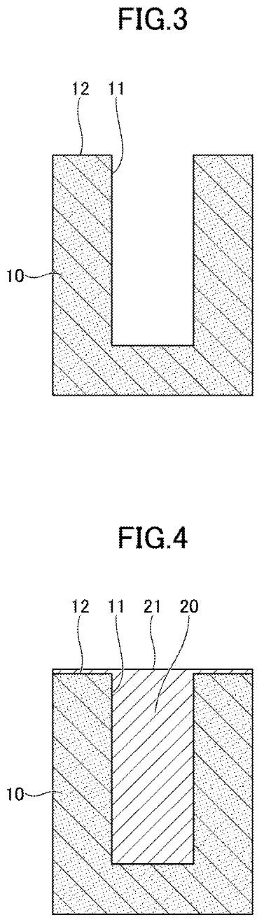

Next, an example of a substrate processing method using the substrate processing system 100 shown in FIG. 1 will be described with reference to FIGS. 2 to 11. FIG. 2 is a flowchart showing an example of the substrate processing method according to an embodiment. FIGS. 3 to 7 are schematic cross-sectional views of the substrate W in each process. FIGS. 8 to 11 are examples of chemical reaction formulae explaining each process.

Here, a process for embedding a silicon-containing film (third silicon-containing film 40) in the recess 11 of the substrate W will be described. The silicon-containing film (third silicon-containing film 40) embedded in the recess 11 is, for example, any one of an SiO film, an SiOC film, an SiOCN film, or the like.

In step S101, the substrate W is prepared.

Here, a carrier C containing the substrate W is attached to one of the load ports 501 to 504. Then, the controller 600 controls the conveying mechanism 402 and the like to convey the substrate W from the carrier C to one of the load lock chambers 301 to 303. Further, the controller 600 controls the conveying mechanism 106 and the like to convey the substrate W from the one of the load lock chambers 301 to 303 to the substrate support of the processing apparatus 101.

FIG. 3 is an example of a schematic cross-sectional view of the substrate W prepared in step S101. Here, the substrate W prepared includes a base part 10. The recess 11 is formed in an upper surface 12 of the base part 10.

A case where the substrate W has the recess 11 in the vertical direction will be described as an example. However, this is non-limiting. The substrate W includes a first recess in the vertical direction and a second recess extending in a lateral direction (horizontal direction) from the side surface of the first recess, and the substrate process shown in FIG. 2 may be a process for embedding a silicon-containing film in the second recess.

In step S102, the first fluidic film 20 is formed on the substrate W by exposing the substrate W to a plasma formed from the first processing gas containing a first silicon-containing gas and a second silicon-containing gas.

Here, the controller 600 controls the gas supply, the plasma former, and the like of the processing apparatus 101 to form a plasma of the first processing gas.

The first silicon-containing gas is an organosilicon compound gas. The first silicon-containing gas is a gas containing a monomer of an organosilicon compound. When the silicon-containing film (the third silicon-containing film 40) to be embedded in the recess 11 is an SiOC film, the first silicon-containing gas contains at least Si, O and C. When the silicon-containing film (the third silicon-containing film 40) to be embedded in the recess 11 is an SiOCN film, the first silicon-containing gas contains at least Si, O, C and N.

The organosilicon compound gas is represented by, for example, the following structural formula (1).

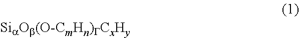

Here, m, n and a are any integers equal to or greater than 1, β, Γ, x and y are any integers equal to or greater than 0, and β and Γ are not 0 at the same time.

Examples of such compounds include alkoxysilane compounds (alkoxysilane-based monomers) in which B is 0 and F is equal to or greater than 1. As the alkoxysilane-based compounds, compounds represented by (R1)ₐSi(—O—R₂)₄₋ₐ (where R1 is one of —CH₃, —C₂H₅, —C₃H₇, —C₂H₃, or —C₂H, R₂ is —CH, or —C₂H₅, and a is 0, 1, 2, or 3) can be used. Specific examples include tetramethoxysilane (TMOS; Si(OCH₃)₄). methyltrimethoxysilane (MTMOS; Si(OCH₃)₃CH₃), tetraethoxysilane (TEOS; Si(OCH₃)₄), dimethyldimethoxysilane (DMDMOS; Si(OCH₃)₂(CH₃)₂), triethoxysilane (SiH(OC₂H₅)₃), trimethoxysilane (SiH(OCH₃)₃), trimethoxy disiloxane (Si(OCH₃)₃OSi(OCH₃)₃), and the like. These compounds may be used alone or in combination of two or more.

Examples of other organosilicon compound gases include methyltrimethoxysilane having an Si-CaHn bond. Examples of still other organosilicon compound gases include silicon compounds represented by SiₛNₜCᵤHᵥ (where s and v are any integers equal to or greater than 1, and t and u are any integers equal to or greater than 0).

The second silicon-containing gas is a gas containing silicon (Si). The second silicon-containing gas is a crosslinking gas for crosslinking a monomer (organosilicon compound). A gas containing silicon, represented by SiₙH₂ₙ₊₂ (where n is an integer equal to or greater than 1), can be used as the second silicon-containing gas. For example, one of silane (SiH₄), disilane (Si₂H₆), trisilane (Si₃H₈), tetrasilane (Si₄H₁₀), higher order silanes, or the like can be used as such a gas containing silicon. In the following description, it is assumed that silane (SiH₄) is used as the second silicon-containing gas.

Here, the ratio of the second silicon-containing gas (crosslinking gas) in the first processing gas used in step S102 is greater than that in the second processing gas used in step S105 described later. That is, the ratio of the second silicon-containing gas (crosslinking gas) in the first processing gas is greater than the ratio of the second silicon-containing gas (crosslinking gas) in the second processing gas. Specifically, the ratio of the second silicon-containing gas (crosslinking gas) in the first processing gas is preferably within the range of 0.29 to 0.375.

In the process of step S102, the processing temperature of the substrate W is preferably in the range of, for example, 20° C. to 100° C. Further, the processing temperature of the substrate W is more preferably in the range of, for example, 25° C. to 50° C.

FIG. 8 is an example of a chemical reaction formula explaining the process of step S102. As shown in FIG. 8, when the organosilicon compound (first silicon-containing gas) and silane (second silicon-containing gas) react with each other, a crosslinking reaction of the organosilicon compound (first silicon-containing gas) is promoted by the silane (second silicon-containing gas), to form a fluidic oligomer. Here, the ratio of the crosslinking gas (second silicon-containing gas) is greater in the first processing gas than in the second processing gas described later, to increase the number of molecules in the fluidic oligomer to be formed. Thus, a first fluidic film 20 having a first viscosity is formed. The first viscosity is higher than a second viscosity described later.

FIG. 4 is an example of a schematic cross-sectional view of the substrate W after being processed in step S102. The fluidic oligomer is generated by the plasma formed from the first processing gas, and the fluidic oligomer flows into the recess 11 to embed the first fluidic film 20 in the recess 11. Further, the first fluidic film 20 is formed to coat the upper surface 12 of the base part 10. An upper surface 21 of the first fluidic film 20 is a flat surface.

In step S103, an annealing process is performed. The annealing process solidifies the first fluidic film 20. The solidified film becomes a first silicon-containing film 25. That is, the annealing process forms the first silicon-containing film 25.

Here, the controller 600 controls the conveying mechanism 106 and the like to convey the substrate W from the processing apparatus 101 to the substrate support of the processing apparatus 102. The controller 600 controls the gas supply, the heater, and the like of the processing apparatus 102 to heat the substrate W in an inert gas (Ar gas) atmosphere and anneal the substrate W. The annealing process in step S103 may be omitted.

In the process of step S103, the processing temperature of the substrate W is, for example, preferably in the range of 400° C. to 600° C. Further, the processing temperature of the substrate W is, for example, more preferably in the range of 450° C. to 550° C.

In step S104, the substrate W is exposed to a plasma formed from the first modifying gas, to modify the first silicon-containing film 25, thereby forming a modified first silicon-containing film 25. Specifically, the first silicon-containing film 25 is densified.

Here, the controller 600 controls the gas supply, the plasma former, and the like of the processing apparatus 102 to form a plasma of the first modifying gas.

The first modifying gas contains an inert gas (Ar gas) and hydrogen (Hz) gas.

Here, the ratio of the hydrogen (H₂) gas in the first modifying gas used in step S104 is less than that in the second modifying gas used in step S107 described later. That is, the ratio of the hydrogen (H₂) gas in the first modifying gas is less than the ratio of the hydrogen (H₂) gas in the second modifying gas.

The pressure in the processing vessel in step S104 is lower than the pressure in the processing vessel in step S107 described later.

The frequency of a high-frequency power supplied for forming a plasma in step S104 is lower than the frequency of a high-frequency power to be supplied for forming a plasma in step S107 described later. The processing apparatus 102 includes, for example, a CCP plasma source as the plasma former. The frequency of the high-frequency power supplied for forming a plasma in step S104 is preferably in the HF band. Specifically, the frequency of the high-frequency power supplied for forming a plasma in step S104 is, for example, 3 MHz to 30 MHz (for example, 13.56 MHz).

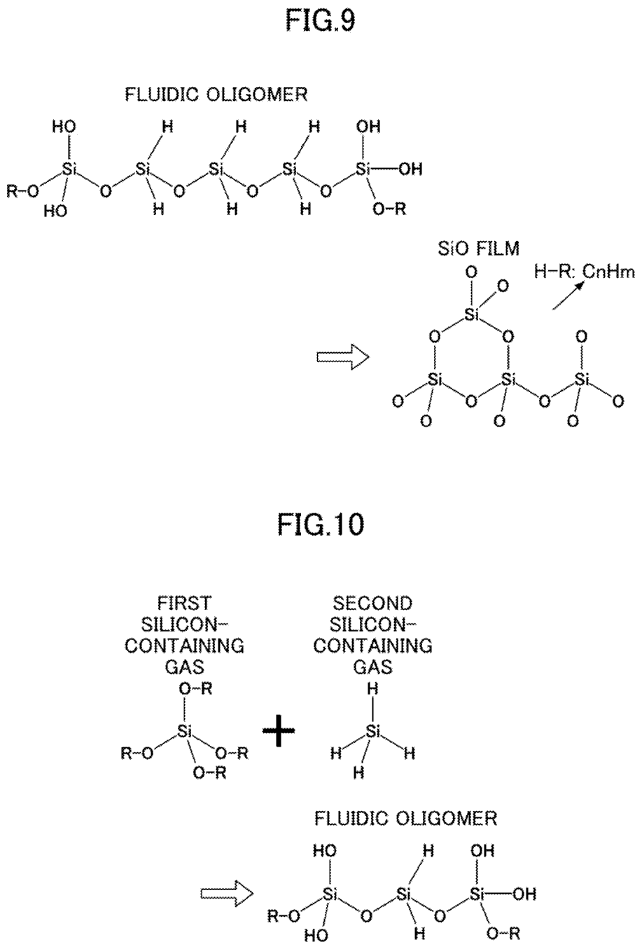

FIG. 9 is an example of a chemical reaction formula explaining the processes of steps S103 and S104. As shown in FIG. 9, the crosslinking reaction of the fluidic oligomer of the first fluidic film 20 is promoted by the annealing process, to form an SiO film (SiOC film or SiOCN film) as the first silicon-containing film 25. The SiO film (SiOC film or SiOCN film) as the first silicon-containing film 25 is densified by the plasma of the first modifying gas.

FIG. 5 is an example of a schematic cross-sectional view of the substrate W after being processed in steps S103 and S104. Here, solidifying and densifying the first fluidic film 20 by the annealing process (S103) and the modifying process (S104) inhibit surface shrinkage and reduce the internal volume of the first silicon-containing film 25 being formed. Here, the first fluidic film 20 has a high viscosity (first viscosity) and inhibits an upper surface 26 of the first silicon-containing film 25 from being dented. In addition, voids 27 are formed in the first silicon-containing film 25 due to the volume reduction.

When a fluidic film having a low viscosity is embedded in the recess and solidified and densified by the annealing process and the modifying process, the first silicon-containing film shrinks and undergoes internal volume reduction while the first silicon-containing film is formed. Here, in the case of the fluidic film having the low viscosity, an unsolidified fluidic film might flow into the voids, thereby forming a dent in the upper surface of the silicon-containing film.

FIG. 13 is an example of a schematic cross-sectional view showing a state of the substrate during a Chemical Mechanical Polishing (CMP) process. Here, a film 220 having recesses 221 is formed on a film 210. A fluidic film having a low viscosity is embedded in the recesses 221, and solidified and densified by the annealing process and the modifying process, to form a silicon-containing film 230. The silicon-containing film 230 shrinks, thereby forming dents 231 in the silicon-containing film 230. When such dents 231 are formed, for example, a polishing agent (slurry) 240 might accumulate in the dents 231 when the substrate is subjected to the CMP process using a polishing pad 300 as shown in FIG. 13 in a subsequent step.

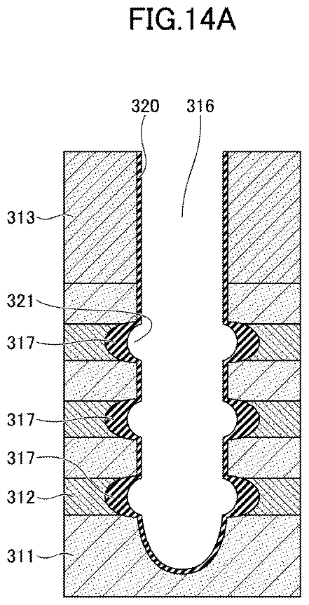

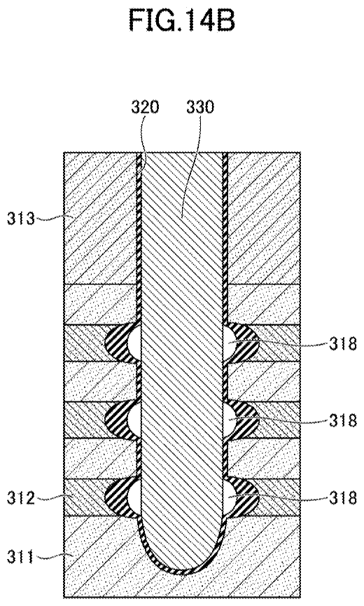

FIGS. 14A and 14B are an example of a schematic cross-sectional view showing a state of the substrate. Here, the substrate has a laminate film in which films 311 and films 312 are laminated alternately and a film 313 is formed thereon. Further, the laminate film includes a first recess 316 formed in a longitudinal direction (vertical direction) and second recesses 317 formed in the films 312 in a lateral direction (horizontal direction) from the first recess 316. Here, a silicon-containing film 320 is formed by embedding a fluidic film in the side walls of the first recess 316 and the second recesses 317 and solidifying and densifying the fluidic film by the annealing process and the modifying process. In the configuration including the lateral second recesses 317 as shown in FIG. 14A, when the silicon-containing film 320 is embedded in the second recesses 317 by using, for example, a fluidic film, dents 321 are formed in the silicon-containing film 320. Therefore, as shown in FIG. 14B, when embedding 330 is performed in the first recess 316 in the next step, the dents 321 in the silicon-containing film 320 might not be filled to form voids 318.

On the other hand, as shown in FIG. 5, when a fluidic film having a high viscosity is embedded in the recess and is solidified and densified by the annealing process and the modifying process, surface shrinkage of the first silicon-containing film 25 can be inhibited and the internal volume of the first silicon-containing film 25 can be reduced. Thus, the upper surface 26 of the first silicon-containing film 25 is prevented from being dented, and a polishing agent is prevented from accumulating during, for example, the CMP process. Further, for example, even in a configuration having the second recesses in the lateral direction, it is possible to inhibit formation of dents in the first silicon-containing film 25, and to prevent voids from being formed when embedding is performed in the first recess in the next step.

In step S105, the second fluidic film 30 is formed on the substrate W by exposing the substrate W to a plasma formed from the second processing gas containing the first silicon-containing gas and the second silicon-containing gas.

Here, the controller 600 controls the conveying mechanism 106 and the like to convey the substrate W from the processing apparatus 102 to the substrate support of the processing apparatus 103. The controller 600 controls the gas supply, the plasma former, and the like of the processing apparatus 103 to form a plasma of the second processing gas.

The first silicon-containing gas of the second processing gas is the same gas as the first silicon-containing gas of the first processing gas. The second silicon-containing gas of the second processing gas is the same gas as the second silicon-containing gas of the first processing gas. The ratio of the second silicon-containing gas (crosslinking gas) in the second processing gas used in step S105 is less than that in the first processing gas used in step S102. That is, the ratio of the second silicon-containing gas (crosslinking gas) in the second processing gas is less than the ratio of the second silicon-containing gas (crosslinking gas) in the first processing gas. Specifically, the ratio of the second silicon-containing gas (crosslinking gas) in the second processing gas is preferably within the range of 0.0385 to 0.074.

In the process of step S105, the processing temperature of the substrate W is preferably, for example, in the range of 20° C. to 100° C. Further, the processing temperature of the substrate W is more preferably, for example, in the range of 25° C. to 50° C.

FIG. 10 is an example of a chemical reaction formula explaining the process of step S105. As shown in FIG. 10, the organosilicon compound (first silicon-containing gas) and silane (second silicon-containing gas) react with each other, to promote a crosslinking reaction of the organosilicon compound (first silicon-containing gas) by the silane (second silicon-containing gas), to form a fluidic oligomer. Here, the ratio of the crosslinking gas (second silicon-containing gas) in the second processing gas is less than that in the first processing gas, and the number of molecules in the fluidic oligomer to be formed is reduced. Thus, the second fluidic film 30 having the second viscosity is formed. The second viscosity is lower than the first viscosity.

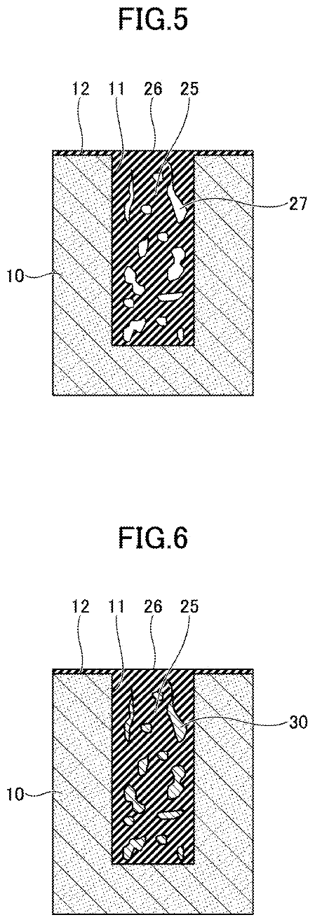

FIG. 6 is a schematic cross-sectional view of the substrate W after being processed in step S105. A fluidic oligomer having a low viscosity is generated by the plasma formed from the second processing gas, and the fluidic oligomer flows into the recess 11 and into the voids 27 in the first silicon-containing film 25, thereby embedding the second fluidic film 30 therein.

In step S106, an annealing process is performed. The annealing process solidifies the second fluidic film 30. The solidified film becomes a second silicon-containing film 35. That is, the annealing process forms the second silicon-containing film 35.

Here, the controller 600 controls the conveying mechanism 106 and the like to convey the substrate W from the processing apparatus 103 to the substrate support of the processing apparatus 104. The controller 600 controls the gas supply, the heater, and the like of the processing apparatus 104 to heat the substrate W in an inert gas (Ar gas) atmosphere and anneal the substrate W. The annealing process in step S106 may be omitted.

In the process of step S106, the processing temperature of the substrate W is preferably, for example, in the range of 400° C. to 600° C. Further, the processing temperature of the substrate W is more preferably, for example, in the range of 450° C. to 550° C.

In step S107, a modified second silicon-containing film 35 is formed by modifying the second silicon-containing film 35 by exposing the substrate W to a plasma formed from the second modifying gas. Specifically, the second silicon-containing film 35 is densified.

Here, the controller 600 controls the gas supply, the plasma former, and the like of the processing apparatus 104 to form a plasma of the second modifying gas.

The second modifying gas contains an inert gas (Ar gas) and hydrogen (H₂) gas.

Here, the ratio of the hydrogen (H₂) gas in the second modifying gas used in step S107 is greater than that in the first modifying gas used in step S104. That is, the ratio of the hydrogen (H₂) gas in the second modifying gas is greater than the ratio of the hydrogen (H₂) gas in the first modifying gas.

The pressure in the processing vessel in step S107 is higher than the pressure in the processing vessel in step S104.

The frequency of a high-frequency power supplied when forming the plasma in step S107 is higher than the frequency of a high-frequency power supplied for forming a plasma in step S104. The processing apparatus 104 includes, for example, a VHF plasma source as a plasma former. The frequency of the high-frequency power supplied when forming the plasma in step S107 is preferably in the VHF band. Specifically, the frequency of the high-frequency power supplied when forming the plasma in step S107 is preferably in the range of 60 MHz to 300 MHz (for example, 180 MHz).

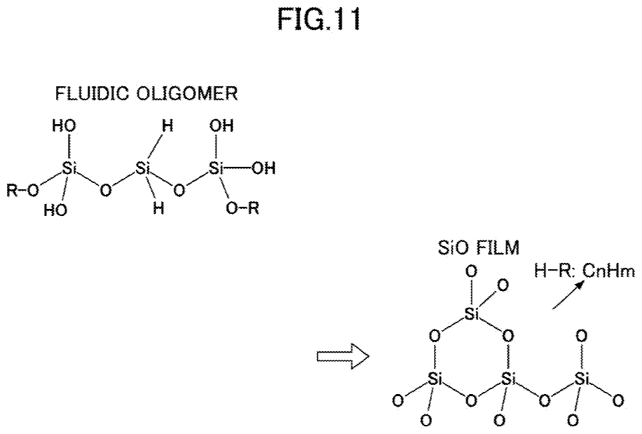

FIG. 11 is an example of a chemical reaction formula explaining the processes of steps S106 and S107. As shown in FIG. 11, the crosslinking reaction of the fluidic oligomer of the second fluidic film 30 is promoted by the annealing process, to form an SiO film (SiOC film or SiOCN film) as the second silicon-containing film 35. The SiO film (SiOC film or SiOCN film) as the second silicon-containing film 35 is densified by the plasma of the second modifying gas.

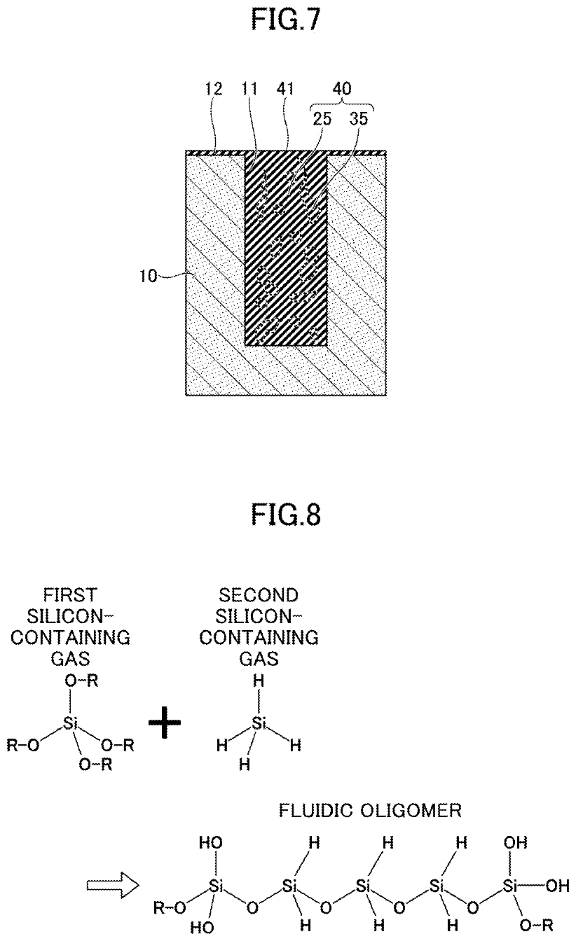

FIG. 7 is a schematic cross-sectional view of the substrate W after being processed in steps S106 and S107. As shown in FIG. 7, the second silicon-containing film 35 is formed in the voids 27. Thus, the third silicon-containing film 40 is formed from the first silicon-containing film 25 and the second silicon-containing film 35.

Further, after the process of step S107, the processes of steps S105 to S107 may be repeated. Thus, the second silicon-containing film 35 can be embedded in the voids remaining in the third silicon-containing film 40.

Then, the controller 600 controls the conveying mechanisms 106 and 402 and the like to convey the substrate W from the processing apparatus 104 to a carrier C via the load lock chambers 301 to 303. Thus, the process shown in FIG. 2 is completed. As described above, the processes of steps S102 to S107 are continuously performed in a vacuum atmosphere.

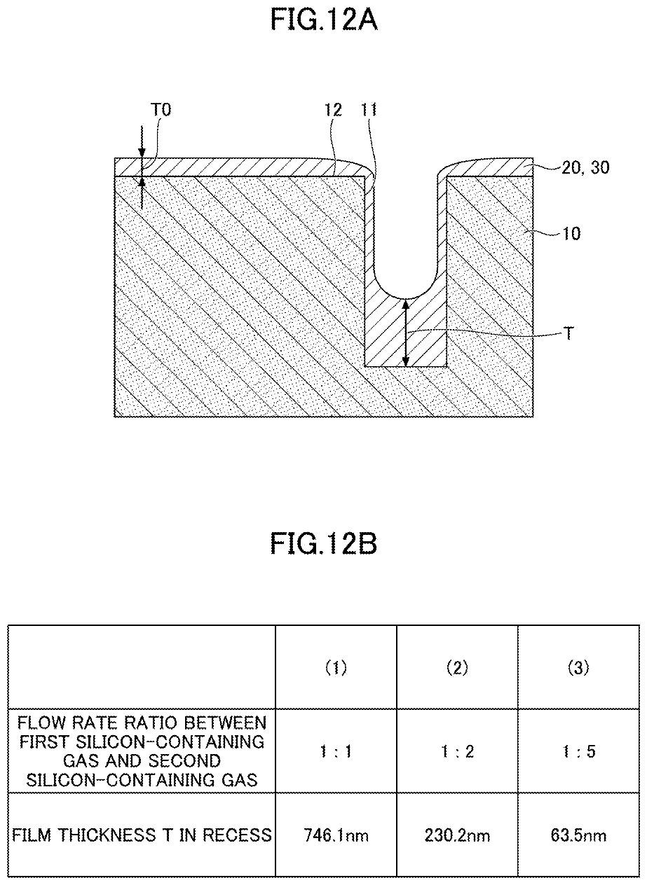

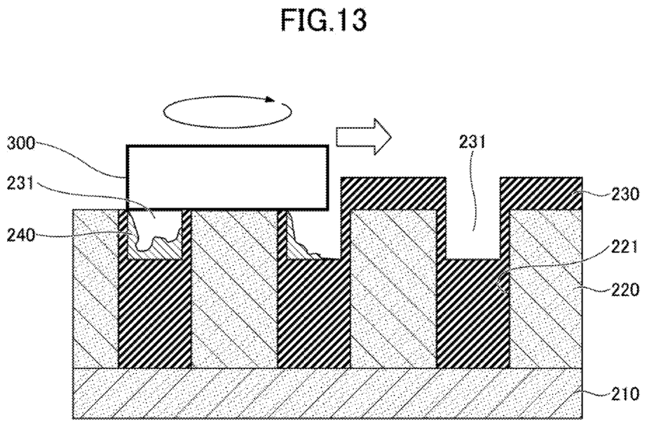

Here, the characteristics of the fluidic films (first fluidic film 20 and second fluidic film 30) formed in steps S102 and S105 will be further described. FIGS. 12A and 12B are examples of a view and a diagram showing the relationship between the ratio of the crosslinking gas and the viscosity of the fluidic film. In FIG. 12A, the fluidic films (20 and 30) were formed on the substrate W including the recess 11. Here, when the film thickness of the fluidic films (20 and 30) formed on the upper surface 12 of the base part 10 was assumed to be a predetermined film thickness TO (100 nm), the fluidity of the fluidic films (20 and 30) was evaluated by the film thickness T of the fluidic films (20 and 30) formed from the bottom surface of the recess 11. The greater the film thickness T, the higher the viscosity, and the lesser the film thickness T, the lower the viscosity.

In FIG. 12B, the film thickness T of the fluidic films formed from the bottom surface of the recess 11 was measured for cases where the flow rate ratio between the first silicon-containing gas (organosilicon compound gas) and the second silicon-containing gas (silane gas) was set to (1) 1:1, (2) 1:2, and (3) 1:5.

As shown in FIGS. 12A and 12B, it can be seen that the lesser the ratio of the second silicon-containing gas (silane gas) to the first silicon-containing gas (organosilicon compound gas), the greater the film thickness T. This indicates that it was possible to control the viscosity (fluidity) of the fluidic films by controlling the flow rate ratio between the first silicon-containing gas (organosilicon compound gas) and the second silicon-containing gas (silane gas).

As described above, in the process of step S102 (the process for forming the first fluidic film 20), the first fluidic film 20 having a high viscosity (first viscosity) is embedded in the recess 11 by increasing the ratio of the cross-linking molecules (second silicon-containing gas) in the first processing gas. Thus, it is possible to form the voids 27 in the first silicon-containing film 25 by reducing the impact of the film thickness change in the annealing process and the modifying process (S103 and S104). In addition, it is possible to inhibit formation of dents in the upper surface 26 of the first silicon-containing film 25. Furthermore, even in the configuration including the second recesses in the lateral direction, it is possible to inhibit formation of dents in the first silicon-containing film 25, and to prevent formation of voids when performing embedding in the first recess in the next step.

On the other hand, in the process of step S105 (the process for forming the second fluidic film 30), the second fluidic film 30 having a low viscosity (second viscosity) can be embedded in the recess 11 and in the voids 27 in the first silicon-containing film 25 by reducing the ratio of the crosslinking molecules (second silicon-containing gas) in the second processing gas.

The process of step S103 (the first annealing process) and the process of step S106 (the second annealing process) may be performed under the same processing conditions.

Further, the plasma formation conditions, such as the ratio between the inert gas (Ar gas) and the hydrogen (H₂) gas, the pressure in the processing vessel, the frequency of the high-frequency power supplied when forming the plasma, and the like are varied between the process of step S104 (the first modifying processing) and the process of step S107 (the second modifying processing).

In the process of step S104 (the first modifying process), more ions of the inert gas (Ar gas) formed as the plasma enter the upper surface 26 of the first silicon-containing film 25 and the surface (interface) than in the process of step S107 (the second modifying processing). Thus, solidification of the upper surface 26 of the first silicon-containing film 25 and the surface (interface) is promoted. Thus, surface shrinkage of the first silicon-containing film 25 can be inhibited. Further, formation of a dent in the upper surface 26 of the first silicon-containing film 25 can be further inhibited.

In the process of step S107 (the second modifying process), the amount of hydrogen radicals formed as the plasma is greater as compared with the process of step S104 (the first modifying process). Thus, the third silicon-containing film 40 (the first silicon-containing film 25 and the second silicon-containing film 35) can be treated (modified) to a greater depth.

The dielectric constant of the first silicon-containing film 25 formed from the first fluidic film 20 and the dielectric constant of the second silicon-containing film 35 formed from the second fluidic film 30 may be varied by varying the ratio of the first silicon-containing gas to the second silicon-containing gas between the first processing gas and the second processing gas. In this way, the dielectric constant of the third silicon-containing film 40 embedded in the recess 11 may be adjusted.

The substrate processing method for embedding the silicon-containing film in the recess has been described above. However, the present disclosure is not limited to the above embodiments and the like, and various modifications and improvements are applicable within the scope of the spirit of the present disclosure described in the claims.

According to one aspect, the present disclosure can provide a substrate processing method and a substrate processing system for embedding a silicon-containing film in a recess of a substrate.

What is claimed is:

1. A substrate processing method for embedding a silicon-containing film in a recess, the substrate processing method comprising:
(a) forming a first fluidic film having a first viscosity in the recess by exposing a substrate to a plasma formed from a first processing gas containing a first silicon-containing gas and a second silicon-containing gas different from the first silicon-containing gas;
(b) forming a first silicon-containing film having voids by modifying the first fluidic film by exposing the substrate to a plasma formed from a first modifying gas;
(c) forming a second fluidic film having a second viscosity lower than the first viscosity in the recess and in the voids in the first silicon-containing film by exposing the substrate to a plasma formed from a second processing gas containing the first silicon-containing gas and the second silicon-containing gas; and
(d) forming a second silicon-containing film by modifying the second fluidic film by exposing the substrate to a plasma formed from a second modifying gas.

2. The substrate processing method according to claim 1,
wherein a ratio of the second silicon-containing gas in the first processing gas in the (a) is greater than a ratio of the second silicon-containing gas in the second processing gas in the (c).

3. The substrate processing method according to claim 2,
wherein the ratio of the second silicon-containing gas in the first processing gas in the (a) is in a range of 0.29 to 0.375, and
the ratio of the second silicon-containing gas in the second processing gas in the (c) is in a range of 0.0385 to 0.074.

4. The substrate processing method according to claim 1,
wherein a processing pressure in the (b) is lower than a processing pressure in the (d).

5. The substrate processing method according to claim 1,
wherein each of the first modifying gas and the second modifying gas contains an inert gas and hydrogen gas.

6. The substrate processing method according to claim 5,
wherein a ratio of the hydrogen gas in the second modifying gas in the (d) is greater than a ratio of the hydrogen gas in the first modifying gas in the (b).

7. The substrate processing method according to claim 1,
wherein a processing temperature in the (a) is lower than a processing temperature in the (b), and
a processing temperature in the (c) is lower than a processing temperature in the (d).

8. The substrate processing method according to claim 1,
wherein processing temperatures in the (a) and the (c) are in a range of 20° C. to 100° C., and
processing temperatures in the (b) and the (d) are in a range of 400° C. to 600° C.;

9. The substrate processing method according to claim 1,
wherein the (c) and the (d) are repeated.

10. The substrate processing method according to claim 1,
wherein the (b) includes:
annealing the first fluidic film; and
exposing the annealed first fluidic film to the plasma of the first modifying gas.

11. The substrate processing method according to claim 1,
wherein the (d) includes:
annealing the second fluidic film; and
exposing the annealed second fluidic film to the plasma of the second modifying gas.

12. The substrate processing method according to claim 1,
wherein the first silicon-containing gas is an organosilicon compound.

13. The substrate processing method according to claim 1,
wherein the second silicon-containing gas is a gas containing silicon represented by SiₙH₂ₙ₊₂ (where n is an integer equal to or greater than 1).

14. The substrate processing method according to claim 1,
wherein the (a), the (b), the (c), and the (d) are continuously performed in a vacuum atmosphere.

15. The substrate processing method according to claim 1,
wherein a frequency of a high-frequency power supplied when forming the plasma in the (d) is higher than a frequency of a high-frequency power supplied when forming the plasma in the (b).

16. The substrate processing method according to claim 15,
wherein the frequency of the high-frequency power supplied when forming the plasma in the (b) is in an HF band, and the frequency of the high-frequency power supplied when forming the plasma in the (d) is in a VHF band.

17. The substrate processing method according to claim 1,
wherein the (a) and the (c) are performed in a same processing vessel.

18. The substrate processing method according to claim 1,
wherein the first silicon-containing film and the second silicon-containing film are each any one of an SiO film, an SiOC film, or an SiOCN film.

19. A substrate processing system configured to embed a silicon-containing film in a recess, the substrate processing system comprising:
a first processing apparatus configured to form a first fluidic film having a first viscosity in the recess by exposing a substrate to a plasma formed from a first processing gas containing a first silicon-containing gas and a second silicon-containing gas different from the first silicon-containing gas;
a second processing apparatus configured to form a first silicon-containing film by modifying the first fluidic film by exposing the substrate to a plasma formed from a first modifying gas;
a third processing apparatus configured to form a second fluidic film having a second viscosity lower than the first viscosity in the recess and in voids in the first silicon-containing film by exposing the substrate to a plasma formed from a second processing gas containing the first silicon-containing gas and the second silicon-containing gas different from the first silicon-containing gas; and
a fourth processing apparatus configured to form a second silicon-containing film by modifying the second fluidic film by exposing the substrate to a plasma formed from a second modifying gas; and
a vacuum conveying chamber connected to the first to fourth processing apparatuses.
